(19) United States
(12) Patent Application Publication
(10) Pub. No.: US 2025/0042144 A1
(43) Pub. Date: Feb. 6, 2025

(54) THERMALLY CONDUCTIVE BOARD

(71) Applicant: TCLAD TECHNOLOGY CORPORATION, Toufen City (TW)

(72) Inventors: Kai-Wei LO, Zhubei City (TW); Kuan-Yu CHEN, Taipei City (TW); Hsin-Lung CHEN, Zhubei City (TW)

(21) Appl. No.: 18/422,501

(22) Filed: Jan. 25, 2024

(30) Foreign Application Priority Data
Aug. 3, 2023 (TW) 112129178

(51) Int. Cl. B32B 15/08; B32B 27/20

(52) U.S. Cl. CPC B32B 27/20; B32B 15/092; B32B 15/20; B32B 2250/03; B32B 2250/40; B32B 2264/1023; B32B 2264/107; B32B 2264/202; B32B 2307/206; B32B 2307/302; B32B 2457/08

(57) ABSTRACT

A thermally conductive board includes a top metal layer, a bottom metal layer, and an electrically insulating but thermally conductive layer (for simplification hereinafter referred to as “thermally conductive layer”) laminated between the top metal layer and the bottom metal layer. The thermally conductive layer satisfies a relation of I˜q^{a}. There is an equivalence relation between I and q; “I” stands for scattering intensity; “q” stands for scattering vector, and “a” stands for the power of q. q ranges from 0.007 Å⁻¹ to 0.1 Å⁻¹, and a ranges from −3 to −4.

### BACKGROUND OF THE INVENTION

### (1) Field of the Invention

The present application relates to a thermally conductive board, and more specifically, to a thermally conductive board with high thermal conductivity.

### (2) Description of the Related Art

In order to manufacture an electronic apparatus with specific functions, various electronic components within the electronic apparatus are assembled onto a substrate. This substrate serves as a carrier for mounting the electronic components, allowing these electronic components to be secured and electrically connected to an external power source. However, these electronic components generate heat during operation, and an excessive accumulation of heat could affect the normal operation of the electronic apparatus. To address the issue of heat accumulation, there are generally two approaches: the first is to add additional heat dissipation components outside the substrate, such as a heat sink, fan, thermal paste, or other heat dissipation components beyond the substrate; the second is to directly enhance the heat-conductive characteristics of the substrate by manufacturing it as a thermally conductive board with excellent thermal conductivity.

For the second approach mentioned above, the thermally conductive board typically consists of two metal layers with a thermally conductive layer laminated between them before the formation of a wiring layer. The top metal layer can be processed to form the wiring layer, while the bottom metal layer serves as a base substrate for thermal conduction, facilitating the dissipation of heat to the external environment. The thermally conductive layer is an electrically insulating layer with good thermal conductivity and low coefficient of thermal expansion (CTE). Conventionally, the thermally conductive layer is made of at least one resin and at least one thermally conductive filler. Improvements in the thermally conductive layer generally focus on the selection of the types of the resin and thermally conductive filler, attempting to achieve the optimal combination of one or more resins and one or more thermally conductive fillers. However, this approach faces the challenge of high complexity in formulation design. For instance, with change of the type of any one of the components (either resin or thermally conductive filler), it is necessary to consider the compatibility of that component with others and address numerous issues at the interface between it and the metal layer. Even after resolving the compatibility and interface issues, achieving the optimal proportion in the formulation remains necessary. If there is more than one type of the selected resin (or thermally conductive filler), the complexity of achieving the optimal proportion increases significantly, not to mention the addition of other additives commonly used in the industry alongside the resin and thermally conductive filler. Due to the aforementioned complexity in formulation, it becomes challenging to simultaneously balance the thermal conductivity and thermal expansion characteristics of the thermally conductive layer.

Obviously, the formulation design, thermal conductivity, and thermal expansion characteristics of the thermally conductive board need immediate improvement.

### SUMMARY OF THE INVENTION

The present invention provides a thermally conductive board with excellent thermal conductivity. More specifically, the thermally conductive board includes a top metal layer, a bottom metal layer, and an electrically insulating but thermally conductive layer laminated therebetween. The composition of the electrically insulating but thermally conductive layer needs only to meet a parameter range to achieve excellent thermal conductivity and thermal expansion characteristics. The parameter range satisfies a relation of I˜q^{a}. “I” stands for scattering intensity; “q” stands for scattering vector, and “a” stands for the power of q; and there is an equivalence relation between I and q. Actually, the parameter range mentioned above refers to the ranges of q and a. q ranges from 0.007 Å⁻¹ to 0.1 Å⁻¹, and a ranges from −3 to −4.

In accordance with an aspect of the present invention, a thermally conductive board includes a top metal layer, a bottom metal layer, and an electrically insulating but thermally conductive layer laminated between the top metal layer and the bottom metal layer. During X-ray irradiation, the electrically insulating but thermally conductive layer satisfies a relation: I˜q^{a}. An equivalence relation exists between/and q. I stands for scattering intensity. q stands for scattering vector, wherein q ranges from 0.007 Å⁻¹ to 0.1 Å⁻¹, and a ranges from −3 to −4.

In an embodiment, a ranges from −3.3 to −3.7.

In an embodiment, q ranges from 0.007 Å⁻¹ to 0.08 Å⁻¹.

In an embodiment, the electrically insulating but thermally conductive layer includes a polymer and a thermally conductive filler, and the thermally conductive filler has a plurality of spherical particles and a plurality of spheroidal particles.

In an embodiment, a packing density of the plurality of spherical particles and the plurality of spheroidal particles ranges from 0.5 to 0.8, wherein the packing density is defined as a value obtained by dividing a combined volume of the plurality of spherical particles and the plurality of spheroidal particles by a volume of the electrically insulating but thermally conductive layer.

In an embodiment, the plurality of spherical particles and the plurality of spheroidal particles are selected from the group consisting of zirconium nitride, boron nitride, aluminum nitride, silicon nitride, aluminum oxide, magnesium oxide, zinc oxide, silicon dioxide, titanium dioxide, and any combination thereof.

In an embodiment, a filling rate of the thermally conductive filler in the electrically insulating but thermally conductive layer ranges from 65% to 92%.

In an embodiment, the electrically insulating but thermally conductive layer has a thermal conductivity ranging from 1.5 W/mK to 17 W/mK.

In an embodiment, the electrically insulating but thermally conductive layer has a coefficient of thermal expansion (CTE) ranging from 8 ppm/° C. to 33 ppm/° C.

In an embodiment, the polymer is selected from the group consisting of bisphenol A epoxy resin, bismaleimide, cyanate ester, phenoxy resin, polysulfone, polyethersulfone, polystyrene, polyphenylene oxide, polyphenylene sulfide, polyamide, polyimide, polyetherimide, polyetherimide/silicone block copolymer, polyurethane, polyester, polycarbonate, polymethyl methacrylate, styrene/acrylonitrile, styrene block copolymers, and any combination thereof.

In accordance with an aspect of the present invention, a thermally conductive gel includes the electrically insulating but thermally conductive layer mentioned above.

In accordance with an aspect of the present invention, a thermally conductive pad includes the electrically insulating but thermally conductive layer mentioned above.

### BRIEF DESCRIPTION OF THE DRAWINGS

The present application will be described according to the appended drawings in which:

FIG. 1 shows a cross-sectional view of a thermally conductive board in accordance with an embodiment of the present invention; and

FIG. 2 and FIG. 3 illustrate the results of small-angle X-ray scattering (SAXS).

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

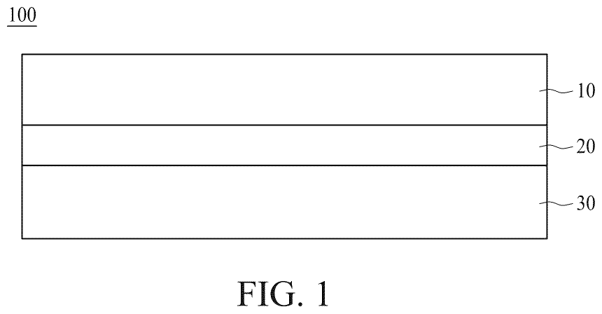

Please refer to FIG. 1, in which shows an aspect of a thermally conductive board 100 of the present invention. The thermally conductive board 100 of the present invention includes a top metal layer 10, a bottom metal layer 30, and an electrically insulating but thermally conductive layer 20 (referred to as “thermally conductive layer” for simplification). The thermally conductive layer 20 physically contacts the top metal layer 10 and the bottom metal layer 30, and is laminated therebetween, forming a triple-layer structure. The top metal layer 10 and the bottom metal layer 30 may be made of copper foil or copper plate, and therefore, the thermally conductive board 100 with double-sided copper is formed. Because of the thermally conductive layer 20, the top metal layer 10 is electrically isolated from the bottom metal layer 30. The top metal layer 10 can be subsequently processed to form a wiring layer to be assembled with various electronic components, while the bottom metal layer 30 serves as a base substrate for thermal conduction, facilitating the dissipation of heat to the external environment. In an embodiment, the top metal layer 10 and the bottom metal layer 30 are made of copper foil, both of which may be processed into the wiring layers, forming a double-sided circuit board. In another embodiment, the top metal layer 10 is copper foil or copper plate, and the bottom metal layer 30 is a metal plate made without copper, such as aluminum plate. The thermally conductive board 100 with double-sided copper can optionally be processed into a single-sided circuit board, a double-sided circuit board, or other types of circuit board depending on the requirements. Besides the wiring layer or the metal base substrate, thermally conductive layer 20 is excellent in thermal conduction, and therefore heat produced from the electronic components can be effectively transferred from the thermally conductive layer 20 to any metal layer for heat dissipation. The thermally conductive layer 20 includes a polymer and a thermally conductive filler. The polymer serves as a matrix for the thermally conductive layer 20, and its thermal conductivity is enhanced by adding the thermally conductive filler.

In order to produce the thermally conductive board 100 with excellent thermal conductivity and a low coefficient of thermal expansion (CTE), the present invention further modifies the composition of the thermally conductive layer 20. The present invention finds that the thermally conductive layer 20 can achieve a higher thermal conductivity and a lower CTE as long as the composition of the thermally conductive layer 20 satisfies a specific relation between X-ray scattering intensity and X-ray scattering vector. More specifically, the thermally conductive layer 20 satisfies a relation of I˜q^{a} during X-ray irradiation. There is an equivalence relation between I and q. I stands for scattering intensity. q stands for scattering vector. q ranges from 0.007 Å⁻¹ to 0.1 Å⁻¹, and a ranges from −3 to −4.

According to Porod law, if a surface is flat, the scattering intensity of X-ray satisfies a relation of I_{(q)}˜Sq⁻⁴. I stands for scattering intensity, S stands for surface area of particles, and q stands for scattering vector. q⁻⁴ corresponds to the factor 1/sin⁴θ in Fresnel equations of reflection. With the emergence of fractal mathematics, the aforementioned relation of Porod law can be reduced to the relation of I˜q^{a} of the present invention. The present invention finds that a composite material exhibits better performance in thermal conductivity and CTE if q and the power of q are restricted to specific ranges. More specifically, vector (q) to be analyzed through SAXS analyzer is below 0.1 Å⁻¹. Therefore, after analyzing a tested sample (i.e., thermally conductive layer 20), a resulting curve of scattering vector (below 0.1 Å⁻¹) against scattering intensity can be plotted. Subsequently, a fitting straight line corresponding to the resulting curve is obtained through curve fitting, and the slope of the fitting straight line is the aforementioned a. According to the present invention, if the slope of the fitting straight line for the tested sample falls within the range of −3.3 to −3.7 in the vector interval between 0.007 Å⁻¹ and 0.08 Å⁻¹, satisfactory results can be obtained in the subsequent verification of thermal conductivity and CTE. The thermal conductivity may reach up to 15 W/mK, and the CTE may be reduced to 9 ppm/° C. Moreover, if the coefficient of determination (i.e., R², R square) for the fitting straight line is about 0.99, the reproducibility of the aforementioned thermal conductivity and CTE is much better. R² represents the proportion of variance between the fitting straight line and the resulting curve. As the value of R² approaches 1, the variability between the fitting straight line and the resulting curve becomes small, indicating a better fit between them. That is, if the variability of the fitting straight line is extremely small and the slope (a) ranges from −3.3 to −3.7, the thermally conductive layer 20 can exhibit excellent thermal conductivity and CTE, and the reproducibility is good for mass production. In an embodiment, considering the measurement error and the permissible error, the slope (a) may vary within the range of −3.3 to −3.9. In another embodiment, the slope (a) may be −3.3, −3.4, −3.5, −3.6, −3.7, −3.8, or −3.9.

In addition, the thermally conductive filler is an inorganic compound, and its particle shape can be roughly categorized as spherical, spheroidal, or fragmental. That is, in terms of particle shape, the thermally conductive filler generally consists of a plurality of spherical thermally conductive particles (referred to as “spherical particles” hereinafter), a plurality of spheroidal thermally conductive particles (referred to as “spheroidal particles” hereinafter), and a plurality of fragmental thermally conductive particles (referred to as “fragmental particles” hereinafter). In the present invention, a packing density of the spherical particles and the spheroidal particles ranges from 0.5 to 0.8. The packing density is defined as a value obtained by dividing a combined volume of the spherical particles and the spheroidal particles by a volume of the thermally conductive layer 20. For example, if the volume of the thermally conductive layer 20 is 10 mm³ (length×width×thickness=10 mm×10 mm×0.1 mm), the combined volume of the spherical particles and the spheroidal particles may vary within the range of 5 mm³ to 8 mm³. In another embodiment, the length and width are the same as described above, but the thickness of the thermally conductive layer 20 is 50 μm (i.e., 0.05 mm); and if the volume of the thermally conductive layer 20 is 5 mm³ (length×width×thickness=10 mm×10 mm×0.05 mm), the combined volume of the spherical particles and the spheroidal particles may vary within the range of 2.5 mm³ to 4 mm³. It is noted that the further the aforementioned a approaches −4, the higher the proportion of the spherical particles and the spheroidal particles increases, thereby reducing the proportion of the fragmental particles. In contrast, the further the aforementioned a approaches −3, the more irregular the particle shape becomes, leading to an increase in the proportion of the fragmental particles. It is understood that the spherical and spheroidal particles have a higher spatial utilization rate, compared to the fragmental particles. This means that when these spherical particles and spheroidal particles are mixed and stacked with each other, they can be packed more densely, occupying more space in the thermally conductive layer 20. However, the packing density is limited to a maximum value. If the packing density of the spherical particles and the spheroidal particles is around or higher than 0.8, it leads to an excessive amount of the thermally conductive filler, which can result in poor processability during blending. In an embodiment, the thermally conductive filler is selected from the group consisting of zirconium nitride, boron nitride, aluminum nitride, silicon nitride, aluminum oxide, magnesium oxide, zinc oxide, silicon dioxide, titanium dioxide, and any combination thereof.

In addition, a filling rate of the thermally conductive filler ranges from 65% to 92%. More specifically, the filling rate refers to a weight percentage of the thermally conductive filler contained in the thermally conductive layer 20. The total weight of the thermally conductive layer 20 is calculated as 100%, and the thermally conductive filler of the present invention accounts for 65% to 92% by weight. In an embodiment, the filling rate of the thermally conductive filler ranges from 81% to 88%. In another embodiment, the filling rate of the thermally conductive filler may be 81%, 82%, 83%, 84%, 85%, 86%, 87%, or 88%. As the filling rate increases, the thermal conductivity increases and CTE decreases in the thermally conductive layer 20. From the above, when the aforementioned a, packing density, and filling rate are simultaneously adjusted in a specific trend, it can effectively enhance the thermal conductivity and reduce the CTE of the thermally conductive layer 20. In an embodiment, the thermal conductivity ranges from 1.5 W/mK to 17 W/mK, and the CTE of the thermally conductive layer 20 ranges from 8 ppm/° C. to 33 ppm/° C. In a preferred embodiment, the thermal conductivity ranges from 8 W/mK to 15 W/mK, and the CTE of the thermally conductive layer 20 ranges from 9 ppm/° C. to 15 ppm/° C.

As for the polymer, it is selected from the group consisting of bisphenol A epoxy resin, bismaleimide, cyanate ester, phenoxy resin, polysulfone, polyethersulfone, polystyrene, polyphenylene oxide, polyphenylene sulfide, polyamide, polyimide, polyetherimide, polyetherimide/silicone block copolymer, polyurethane, polyester, polycarbonate, polymethyl methacrylate, styrene/acrylonitrile, styrene block copolymers, and any combination thereof. In an embodiment, the polymer is made of at least one thermosetting resin, such as the aforementioned bisphenol A epoxy resin, bismaleimide and/or cyanate ester. In another embodiment, the polymer includes a thermosetting resin as its major constituent, with the addition of a thermoplastic resin to enhance the adhesion between the binding materials and the metal layer, wherein the thermoplastic resin may be the aforementioned phenoxy resin, polysulfone, polyethersulfone, polystyrene, polyphenylene oxide, polyphenylene sulfide, polyamide, polyimide, polyetherimide, polyetherimide/silicone block copolymer, polyurethane, polyester, polycarbonate, polymethyl methacrylate, styrene/acrylonitrile, and/or styrene block copolymers.

To further verify the performance of thermally conductive board 100 of the present invention, various tests were conducted, and the results were summarized in Table 1 below.

TABLE 1

| | | | Filling | Thermal | CTE |
|---|---|---|---|---|---|
| | | Packing | rate | conductivity | (ppm/ |
| Group | α | density | (wt %) | (W/mK) | ° C.) |
| E1 | −3.31 | 0.52 | 67 | 1.7 | 32 |
| E2 | −3.42 | 0.55 | 77 | 2.0 | 28 |
| E3 | −3.47 | 0.57 | 81 | 3.0 | 25 |
| E4 | −3.57 | 0.68 | 86 | 8.0 | 15 |
| E5 | −3.60 | 0.70 | 88 | 12.0 | 10 |
| E6 | −3.62 | 0.72 | 90 | 15.0 | 9 |
| C1 | −3.00 | 0.45 | 50 | 1.5 | 55 |
| C2 | −3.50 | 0.59 | 81 | 3.3 | 25 |
| C3 | −3.55 | 0.61 | 81 | 3.6 | 25 |

As shown in Table 1, groups E1 to E6 represent embodiments E1 to E6 of the present invention, and groups C1 to C3 represent comparative examples C1 to C3. In each one of the embodiments E1 to E6, the size of the thermally conductive board 100 is “10 mm×10 mm” in top view; the top metal layer 10 and the bottom metal layer 30 are copper plates, each with a thickness of 0.3 mm; and the thermally conductive layer 20 has a thickness of 100 μm and consists of the polymer and the thermally conductive filler. The size in top view and thickness of each layer of the comparative examples C1 and C3 are the same as those of the embodiments E1 to E6. In the embodiments E1 to E4 and the comparative examples C1 to C3, the polymer is epoxy resin, and the thermally conductive filler is aluminum oxide. In the embodiments E5 to E6, the polymer is epoxy resin, and the thermally conductive filler is aluminum nitride.

“a” refers to the power of q in the equivalence relation of I˜q^{a}. After analyzing through SAXS analyzer, the resulting curve of scattering vector q against scattering intensity I can be plotted, and the value of a can be calculated accordingly. During SAXS analysis, the exposure time is 0.5 seconds; the exposure period is 0.501 seconds; the wavelength is 0.8259 Å; the beam energy is 1.501×10⁴ eV; and the distance between the tested sample and the analyzer is 3.09 meters.

“Packing density” refers to the value obtained by dividing the combined volume of the spherical and spheroidal particles by the volume of the thermally conductive layer. Technically, the packing density is the spatial utilization rate of the spherical and spheroidal particles. If the packing density reaches 1, it means that the thermally conductive layer is entirely occupied by the spherical and spheroidal particles.

“Filling rate” refers to the filling rate of the thermally conductive filler. More specifically, the filling rate represents the weight percentage of the thermally conductive filler contained in the thermally conductive layer.

As shown in Table 1, the present invention seeks the optimal value range of a according to the equivalence relation of I˜q^{a} from Porod law. As the scattering vector q ranges from 0.007 Å⁻¹ to 0.08 Å⁻¹, the value of a may vary within the range of −3.31 to −3.62. It is noted that in the embodiments E1 to E6, since the value of a decreases from −3.31 to −3.62, the packing density correspondingly increases from 0.52 to 0.72. As mentioned earlier, the proportion of the spherical and the spheroidal particles increases higher as the value of a approaches −4 further. Compared with the fragmental particles, the spherical and the spheroidal particles can be packed more densely in a specific space.

Please refer to the embodiments E1-E2 and the comparative example C1. The comparative example C1 has the highest value of a, precisely −3, indicating that the thermally conductive filler predominantly includes the irregular fragmental particles. Consequently, the packing density of the comparative example C1 is very low (i.e., 0.45), resulting in the lowest filling rate (50 wt %) and thermal conductivity (1.5 W/mK), and the highest CTE (55 ppm/° C.). However, in the embodiments E1-E2, as the value of a shifts toward −4 (i.e., from −3.31 to −3.42), the packing density correspondingly increases from 0.45 to the range of 0.52 to 0.55. This increase in spatial utilization rate leads to a rise in thermal conductivity to the range of 1.7 W/mK to 2.0 W/mK, and a significantly reduction in CTE to below 32 ppm/° C.

It is understood that the filling rate refers to the weight percentage of all shapes of the thermally conductive filler, while the packing density refers to the density of the thermally conductive filler in specific shapes (i.e., spherical and spheroidal). To further explain that the value of a positively correlates with the packing density, the filling rate is fixed (i.e., 81%) in the embodiment E3 and the comparative examples C2-C3. As shown in Table 1, under the same filling rate, the value of a in the comparative examples C2-C3 is closer to −4. Consequently, the packing density increases from 0.59 to 0.61. Likewise, this increase in spatial utilization rate leads to a rise in thermal conductivity to the range of 3.3 W/mK to 3.6 W/mK. However, there is no positive correlation with CTE.

According to the information from the embodiments E1-E3 and the comparative examples C1-C3, it is clearly that the value of a positively correlates with both the packing density and the thermal conductivity. Additionally, under the same filling rate, the value of a and the packing density have no significant effect on CTE. Consequently, in the embodiments E4-E6, the value of a is adjusted closer to −4 while increasing the filling rate. Furthermore, the thermally conductive filler in the embodiments E5 and E6 is replaced with aluminum nitride to demonstrate that the present invention can apply to a different thermally conductive filler. As shown in Table 1, the thermal conductivity and CTE may vary within the range of 8.0 W/mK to 15.0 W/mK and 9 ppm/° C. to 15 ppm/° C., respectively, when the value of a ranges from −3.57 to −3.62, the packing density ranges from 0.68 to 0.72, and the filling rate ranges from 86% to 90%. This indicates that adjusting the value of a, packing density, and filling rate can be used to improve both the thermal conductivity and CTE of the device, thereby providing the thermally conductive layer 20 with higher thermal conductivity and lower CTE. The adjustments for the value of a, the packing density, and the filling rate mentioned above can also be applied to different thermally conductive fillers, achieving the same technical effect.

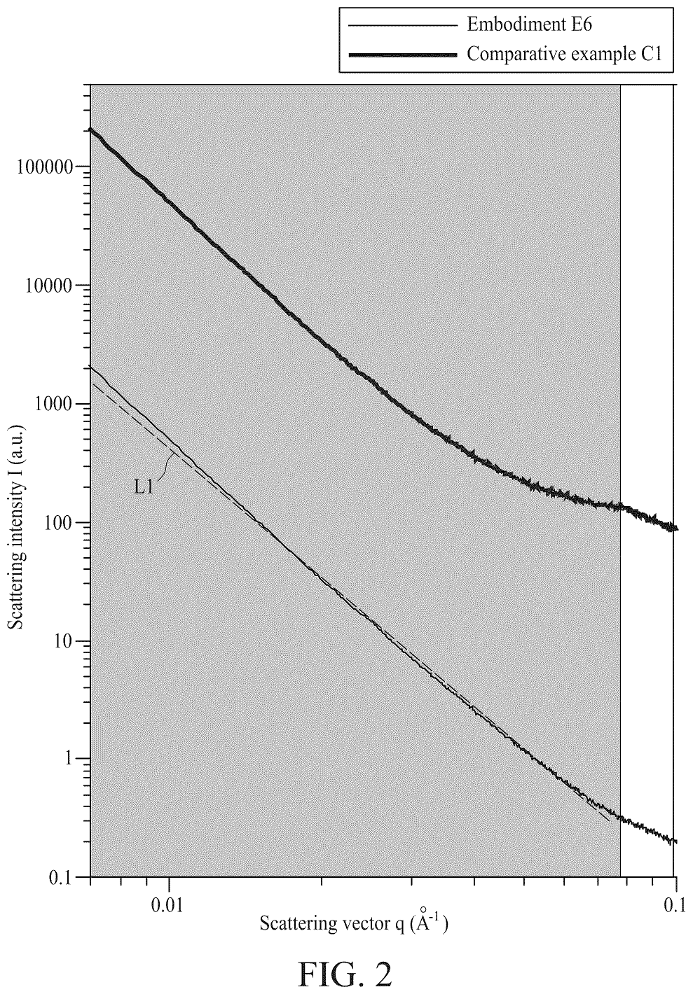

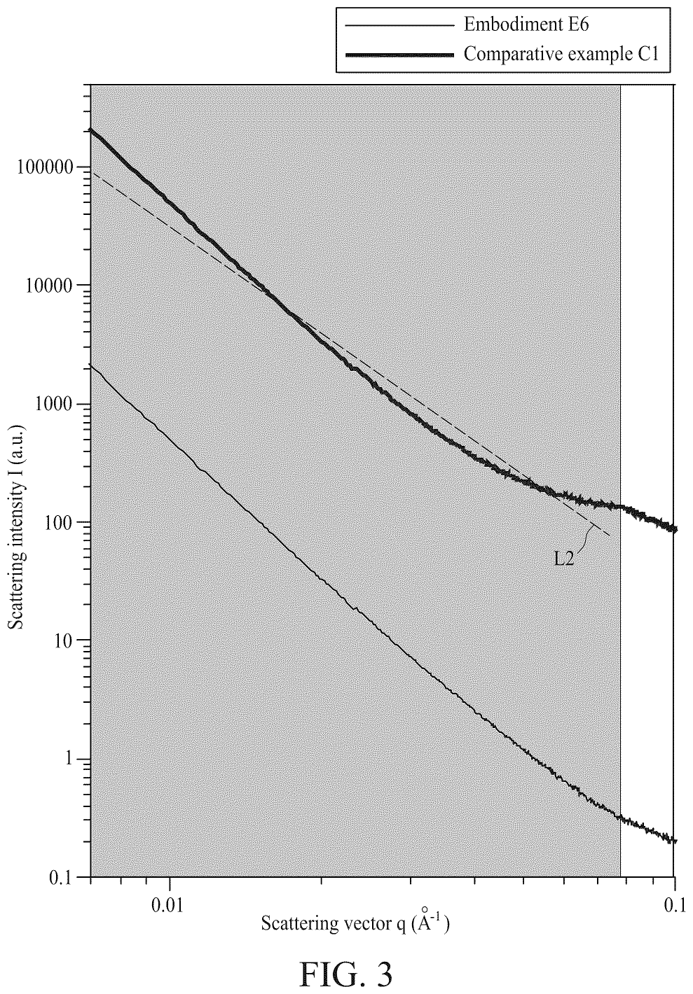

Please refer to FIG. 2 and FIG. 3, which show the results of SAXS analysis for the thermally conductive layers in accordance with the embodiment E6 and the comparative example C1. It should be noted that, for clarity and case of discussion, the comparison in both figures is made between the best embodiment of the present invention (i.e., embodiment E6) and the comparative example C1. The X-axis indicates the scattering vector q, and the Y-axis indicates the scattering intensity I. The slender curve at the lower section of the figure depicts the analysis result of the embodiment E6 of the present invention, while the bold curve above depicts the analysis result of the comparative example C1. In FIG. 2, a straight line (referred to as “first fitting line L1” hereinafter) can be obtained through curve fitting corresponding to the slender curve of the embodiment E6 of the present invention. The slope of the first fitting line L1 is −3.62, and R² is 0.99. In FIG. 3, another straight line (referred to as “second fitting line L2” hereinafter) can be obtained through curve fitting corresponding to the bold curve of the comparative example C1. The slope of the second fitting line L2 is −3, and R² is 0.97. The slope of either the first fitting line L1 or the second fitting line L2 corresponds to the value of a shown in Table 1. As described above, the present invention finds that the thermal conductivity can be significantly enhanced as long as the slope of the first fitting line L1 approaches −4 further. Therefore, if all parameters should be taken into consideration when designing the composition of the thermally conductive layer 20, the value of a is put as top priority. If the value of a does not meet an expected criterion, there is no need for further measurement of thermal conductivity, CTE, or other thermal parameters. For example, a composite material (including the polymer, thermally conductive filler, and/or other additives) is prepared for the fabrication of a thermally conductive layer 20. If the objective is to obtain the thermally conductive layer 20 with the highest thermal conductivity (i.e., the thermal conductivity in the embodiment E6), a target value of a can be set at −3.62 for the thermally conductive layer 20 to be made from the composite material. Once the thermally conductive layer 20 is fabricated from the composite material, the value of a of the thermally conductive layer 20 can be measured. If the thermally conductive layer 20 made from the composite material exhibits a value of a deviating from −3.62, there is no need to do further tests (e.g., tests of thermal conductivity, CTE, or other thermal parameters) for the thermally conductive layer 20. In this way, the present invention firstly specifies a target value of a, facilitating the achievement of a better thermally conductive layer 20 while saving unnecessary verification time. This enhances the efficiency in conducting material improvement.

Although the present invention is exemplified by the structure of FIG. 1 and the data of Table 1, the present invention is not limited thereto. The present invention can apply to other thermally conductive materials, such as thermally conductive gel, thermally conductive pad, or the like. For example, in Taiwan Patent No. M530015 filed on Jun. 24, 2016, Applicant disclosed various thermally conductive gels, which are included in the scope of the present invention. The electrically insulating but thermally conductive layer of the present invention can apply to a thermally conductive gel with suitable adhesive property and low flowability. This thermally conductive gel can be attached on the surface of a circuit board, and gaps between electronic components on the circuit board can be filled with the thermally conductive gel. In another embodiment, a thermally conductive pad can be made by using the same materials as disclosed in the electrically insulating but thermally conductive layer of the present invention. The thermally conductive pad is designed to be attached to the back surface of a fin-like heat sink. Consequently, the thermally conductive pad based on the present invention can be disposed between a circuit board and the fin-like heat sink.

The above-described embodiments of the present invention are intended to be illustrative only. Numerous alternative embodiments may be devised by persons skilled in the art without departing from the scope of the following claims.

1. A thermally conductive board, comprising:
a top metal layer;
a bottom metal layer; and
an electrically insulating but thermally conductive layer laminated between the top metal layer and the bottom metal layer, wherein the electrically insulating but thermally conductive layer satisfies a relation during X-ray irradiation:
I˜q^{a}, wherein:
an equivalence relation exists between I and q;
I stands for scattering intensity; and
q stands for scattering vector, wherein q ranges from 0.007 Å⁻¹ to 0.1 Å⁻¹, and a ranges from −3 to −4.

2. The thermally conductive board of claim 1, wherein a ranges from −3.3 to −3.7.

3. The thermally conductive board of claim 2, wherein q ranges from 0.007 Å⁻¹ to 0.08 Å⁻¹.

4. The thermally conductive board of claim 3, wherein the electrically insulating but thermally conductive layer comprises a polymer and a thermally conductive filler, and the thermally conductive filler has a plurality of spherical particles and a plurality of spheroidal particles.

5. The thermally conductive board of claim 4, wherein a packing density of the plurality of spherical particles and the plurality of spheroidal particles ranges from 0.5 to 0.8, wherein the packing density is defined as a value obtained by dividing a combined volume of the plurality of spherical particles and the plurality of spheroidal particles by a volume of the electrically insulating but thermally conductive layer.

6. The thermally conductive board of claim 5, wherein the plurality of spherical particles and the plurality of spheroidal particles are selected from the group consisting of zirconium nitride, boron nitride, aluminum nitride, silicon nitride, aluminum oxide, magnesium oxide, zinc oxide, silicon dioxide, titanium dioxide, and any combination thereof.

7. The thermally conductive board of claim 6, wherein a filling rate of the thermally conductive filler in the electrically insulating but thermally conductive layer ranges from 65% to 92%.

8. The thermally conductive board of claim 7, wherein the electrically insulating but thermally conductive layer has a thermal conductivity ranging from 1.5 W/mK to 17 W/mK.

9. The thermally conductive board of claim 8, wherein the electrically insulating but thermally conductive layer has a coefficient of thermal expansion (CTE) ranging from 8 ppm/° C. to 33 ppm/° C.

10. The thermally conductive board of claim 6, wherein the polymer is selected from the group consisting of bisphenol A epoxy resin, bismaleimide, cyanate ester, phenoxy resin, polysulfone, polyethersulfone, polystyrene, polyphenylene oxide, polyphenylene sulfide, polyamide, polyimide, polyetherimide, polyetherimide/silicone block copolymer, polyurethane, polyester, polycarbonate, polymethyl methacrylate, styrene/acrylonitrile, styrene block copolymers, and any combination thereof.

11. A thermally conductive gel comprising the electrically insulating but thermally conductive layer of claim 6.

12. A thermally conductive pad comprising the electrically insulating but thermally conductive layer of claim 6.
